(19) United States
(12) Patent Application Publication
(10) Pub. No.: US 2010/0182765 A1
(43) Pub. Date: Jul. 22, 2010

(54) RF/EMI SHIELD

(75) Inventors: Robert L. Vadas, Noblesville, IN (US); Timothy Arthur Eldon, Carmel, IN (US); Scott E. Post, Noblesville, IN (US); Kurt Eric Gilbertson, Peru, IN (US)

Correspondence Address: DELPHI TECHNOLOGIES, INC;LEGAL STAFF - M/C 483-400-402, 5725 DELPHI DRIVE, PO BOX 5052, TROY, MI, 48007, US

(73) Assignee: DELPHI TECHNOLOGIES, INC., Troy, MI (US)

(21) Appl. No.: 12/356,812

(22) Filed: Jan. 21, 2009

(51) Int. Cl. H05K 9/00

(52) U.S. Cl. 361/818; 361/816

(57) ABSTRACT

An RF/EMI shield has a planar conductive element and a plurality of solder spheres extending around the edges making electrical and mechanical contact with the conductive element to form a shield which can be soldered in a surface mount process directly over components needing shielding. The solder spheres have a diameter sufficient to provide the desired clearance between the shielding element and the component being shielded and a melting temperature equivalent to existing solder contacts to which the shield is bonded.

### TECHNICAL FIELD

The present invention relates to a shield against RF and EMI interference and particularly one which employs a ball grid array (BGA) mounting.

### BACKGROUND OF THE INVENTION

With the continued miniaturization of electrical circuits and circuit boards, the use of conventional radio frequency interference (RFI) and electromagnetic interference (EMI) shielding has become an increasing challenge. In the past, shields utilizing pre-tinned tabs have been placed through slots in the circuit board to cover a circuit desired to be shielded. The tabs are then twisted to pull the shield tightly against the board and subsequently wave soldered to ensure electrical contact with a shielding ground connection.

Another type of shield employed is the V-groove shield which utilizes pre-tinned V-grooves inserted through holes in a circuit board. These also require the mechanical step of twisting the mounting tabs to pull the shield tightly against the board and subsequently wave soldering to make an electrical connection. As component density increases, the available real estate on a circuit board is at a premium, and designs become more constrained making the use of such conventional shielding techniques even more difficult.

There exists a need, therefore, for an improved smaller shielding structure which is cost effective as compared to the pre-existing shielding techniques.

### SUMMARY OF THE INVENTION

The system of the present invention overcomes the labor intensive and cost of existing RF/EMI shielding structure and techniques by employing a shield comprising a substrate having a planar conductive element placed on one side thereof and a plurality of solder spheres extending around the edges and making electrical and mechanical contact with the conductive element to form a shield cover which can be soldered in a surface mount process directly over components needing shielding. The solder spheres have a diameter sufficient to provide the desired clearance between the shielding element and the component being shielded and a melting temperature equivalent to the existing solder contacts to which the shield is bonded.

In one embodiment, the shielding element was a thin film conductive material, such as copper. In other embodiments, the shielding element may comprise a wire mesh or printed grid having a size selected to block selected high frequency interference. The spacing of the solder spheres is likewise selected to provide shielding for the gap between the conductive element and the circuit board to which the shield is mounted.

In another embodiment of the invention, the shield may be divided into several sections by a plurality of lines of solder spheres separating the shield into separate areas for shielding individual components on the circuit board from adjacent components. In yet another embodiment of the invention, the shield may comprise a plurality of rows of solder spheres in staggered or aligned relationship to improve the shielding of the circuit component.

Such a shield system can be employed to piggyback over existing ball-grid array circuit structure to provide the desired shielding or on other conventional circuit component mounting structures. The resultant seal is a relatively inexpensive component which is easily assembled to an existing circuit to provide the desired RF/EMI shielding with a minimum of labor.

These and other features, advantages and objects of the present invention will be further understood and appreciated by those skilled in the art by reference to the following specification, claims and appended drawings.

### BRIEF DESCRIPTION OF THE DRAWINGS

The present invention will now be described, by way of example, with reference to the accompanying drawings, in which:

FIG. 1 is a perspective view of a circuit board with a ball-grid array (BGA) circuit mount overlaid by a stacked BGA shield of the present invention;

FIG. 2 is a perspective underside view of the shield of the present invention;

FIG. 3 is a greatly enlarged fragmentary cross-sectional view of the BGA shield and connection to the circuit board, as shown in FIG. 1;

FIG. 4 is a bottom perspective view of a BGA shield according to the present invention divided into two zones;

FIG. 5 is a bottom perspective view of a BGA shield of the present invention, showing an alternative shape for a particular application;

FIG. 6 is a bottom perspective view of a BGA shield of the present invention employing a conductive wire mesh for the shielding element; and

FIG. 7 is a bottom perspective view of the BGA shield of the present invention showing the use of multiple rows of solder spheres for attachment to a circuit board.

### DESCRIPTION OF THE PREFERRED EMBODIMENT

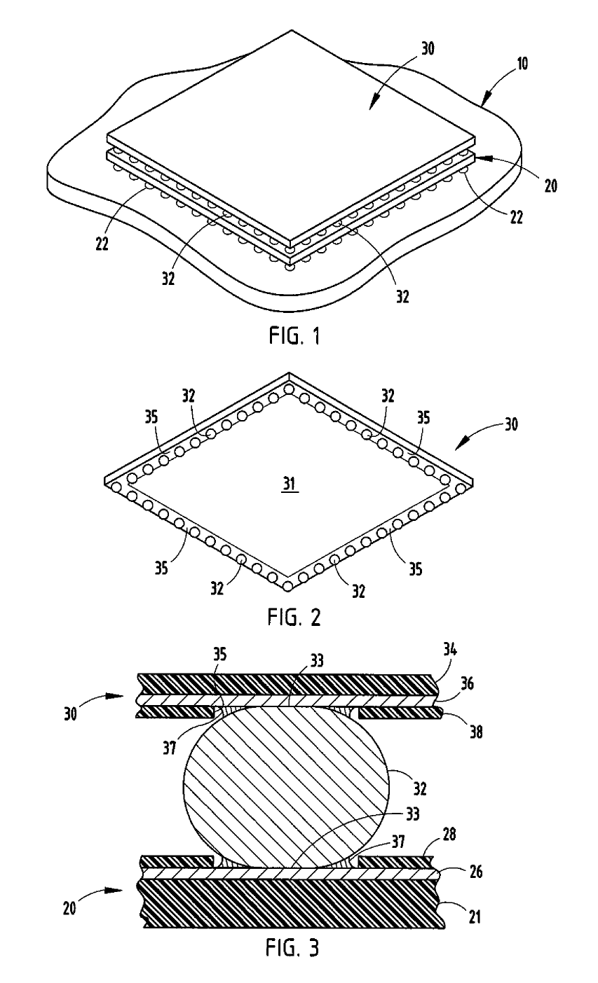

Referring initially to FIG. 1, there is shown a circuit board 10 for an electrical circuit, such as a satellite digital audio radio (SDAR) or other circuit which includes RF components which can be sensitive to RF/EMI interference. Circuit board 10 includes, in this example, a BGA circuit package 20 including soldering spheres 22 which couple the circuit components contained within package 20 to conductive pads on the circuit board for intercoupling the BGA circuit to the remaining circuit components. The components contained in the BGA circuit 20 are RF/EMI sensitive and are shielded by the BGA shield 30 of the present invention, which likewise includes a plurality of solder spheres 32 extending around the edges thereof, as best seen in the FIG. 2 underside perspective view of the BGA shield 30 of the present invention.

Shield 30, as shown in FIG. 2, can be made of commercially available circuit board material, such as Chem 1, 2 or 3 or a FR4 material. Each of these comprise a nonconductive substrate 34 (FIG. 3), which is a relatively thin substrate having a thickness of, for example, about 0.025 inches, although it can range from about 0.015 inches to about 0.040 inches in some embodiments. Substrate 34 can be paper or other suitable material to which there is bonded a conductive shielding element or layer 36, typically of copper, which has generally the same configuration as that of the substrate. The central area 31 is covered with a solder mask, leaving bare copper edges 35, upon which the solder spheres 32 are placed in spaced relationship along each of the edges of the BGA shield 30.

The solder spheres are made of a 63/37 eutectic solder material or SAC 305 lead-free alloy. This solder has a molten temperature of about 183° C. and 217° C., respectively, equivalent to the solder paste used to attach the spheres 32 to the edges of the shield 30. The spheres 32 have a diameter of from about 1 mil to about 1.8 mil and can vary depending upon the size of the circuit component to which the shield is applied. In one application, they had a diameter of about 1.6 mil and were spaced apart from one another by about 1 mil. As used herein, the term “sphere” as used to describe the solder spheres 22 means a generally rounded ball-like structure that may not be perfectly spherical but can deviate, such as being ellipsoidal, as long as they function to hold the conductive element in a desired position with respect to a circuit element being shielded.

The shield 30 need not be piggybacked on top of an existing BGA circuit package but can be applied to any circuit board with surface-mounted components which are sensitive to RF and EMI interference. The solder spheres 32 are placed on the edges of the substrate in contact with the conductive shield material and heated by standard techniques sufficiently to bond to the shielding element holding them in place until the shield is subsequently placed on the main circuit board 10 and heated by standard hot air methods to surface mount the shield to conductive pads or conductors surrounding the electrical component being shielded. The solder spheres will bond to contact electrodes or pads which are typically grounded to provide the desired shielding to the electrical component over which the shield is placed as seen in FIG. 3. The spacing between the spheres is selected to be sufficiently close to effectively block RF and EMI frequencies which could interfere with the operation of the circuit being shielded and typically has a spacing of about 1/20 of the wavelength to be blocked. For a frequency of 14.4 GHz, this would be about 1 mm. For 2.4 GHz, the spacing can be about 6 mm.

The solder spheres 33 are located on shield 30 by three methods. The first method is by discrete placement using standard surface mount technology (SMT) equipment by placing the spheres in tape and reel or by using bulk feeds in the SMT equipment. The spheres are picked from the tape and reel and placed in the pre-deposited solder paste. The second method is to use an IC fabrication machine which place flux and gang pick the solder spheres for placement in the flux. The third method is to use a SMT solder printer machine to screen print the spheres onto the paste or flux on the board.

There are two methods of bonding the spheres 33 to the shield 30. The first method is to use flux such as 37 shown if FIG. 3. This is the method most used with the IC machines. The second method is to use solder paste (also illustrated as 37 in FIG. 3) as in the SMT environment. By depositing solder paste, standard SMT processes can be employed.

The shields 30 do not require wave soldering as it is a SMT process. The solder spheres are first bonded to the shield as described above during the construction of the shield. The shields 30 are then mounted to the package 20 or to a circuit board by placing them as discrete components in the SMT process. They are then processed in the SMT reflow oven, bonding the solder spheres to the main circuit board. After the placement of the solder spheres, they are held on the board by either the tackiness of the flux or the adhesion of the solder paste prior to reflowing the sphere to the circuit board pad.

FIG. 3 is an enlarged cross-sectional view of the shield 30 of the present invention, which includes the substrate 34, the conductive shielding element 36 bonded thereto, and a solder sphere 32 which is soldered to the shielding element 36 by a solder joint 33 and to the circuit conductor 26 of the circuit board 21 to which the shield 30 is attached, again, by a solder joint 33. Areas of the BGA shield 30 and circuit board 21, which do not have an exposed conductive surface, are covered by a solder mask 38 and 28, respectively, as seen in FIG. 3.

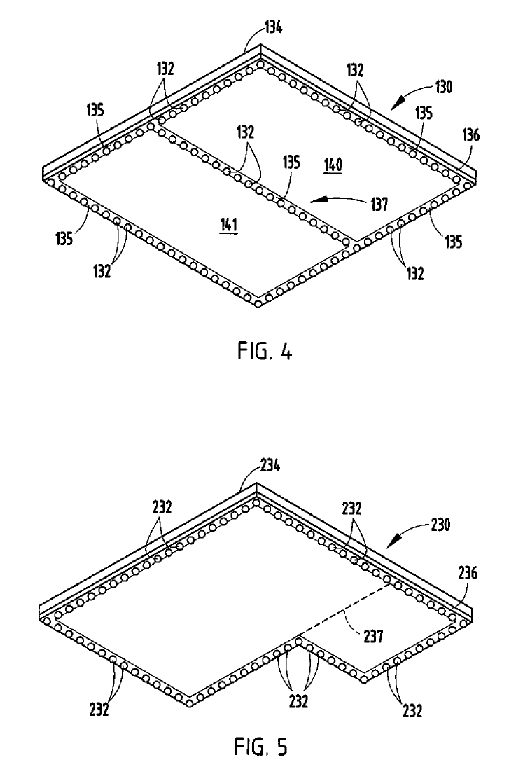

As seen in FIG. 4, a zoned BGA shield 130 is shown which also includes a substrate 134 with a conductive shielding element 136 overlying and bonded to the substrate 134. Shield 130 is fabricated in the same manner as shield 30 but is divided into sections 140 and 141 by a row 137 of spheres 132. Solder spheres 132 are soldered to the exposed conductive edges 135 of the shield along each of the edges and an exposed conductive strip 135 for the row 137 of such spheres which bisect the shield 130 into two generally rectangular sections 140 and 141. These sections are located to overlie separate circuit components on a circuit board, such as board 10 shown in FIG. 1, which has adjacent components, such as microprocessors, which may be subject to RF/EMI interference. Thus, shield 130, shown in FIG. 4, can be employed for isolating circuit components from one another on the same circuit board. The geometry of a multiple section shield such as shield 130 can be selected to include any number of a plurality of sections such as 140 and 141 and of any desired shape depending upon the circuit components being shielded and their location on a circuit board.

FIG. 5 is an alternative embodiment of the invention showing a shield 230 which likewise includes a substrate 234 and shielding element 236 made of a conductive material. This shield is likewise fabricated of the same material and by the same process as shields 30 and 130. The peripheral edge of the generally L-shaped shield 230 is surrounded by solder spheres 232 of the same size, shape, spacing, and material as described in the previous embodiments. The L-shaped circuit 230 is illustrative of only one of any number of configurations that the shield may be formed into for covering RF components to be shielded. Thus, the shield can take any geometric shape as necessary for providing the shielding for a single or group of components desired to be shielded. The irregular shape of shield 230 can also be divided into sections as illustrated by the phantom line 237 representing a dividing line of spheres similar to that shown in FIG. 4.

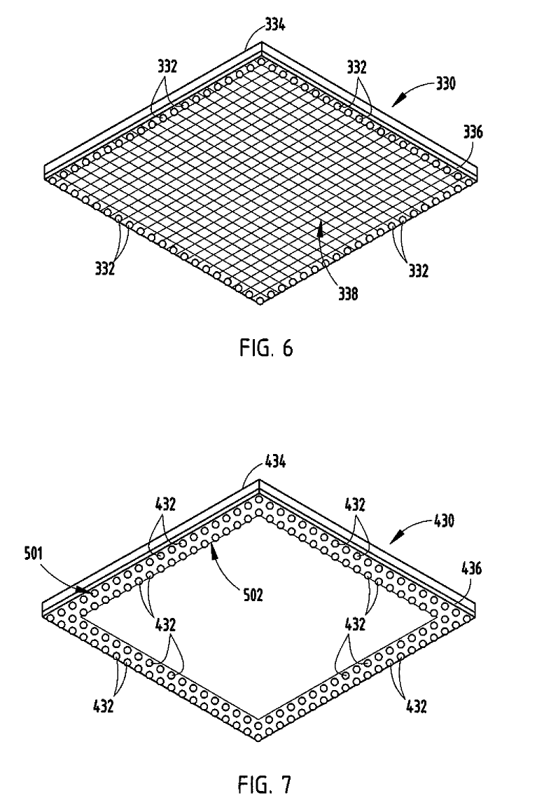

FIG. 6 is an alternative embodiment of the invention showing a shield 330 which includes, instead of a solid conductive shield element such as 36,136 and 236 in the previous embodiments, a wire mesh 338 which is bonded to a nonconductive substrate 334 and is made of a conductive material, such as copper mesh. The mesh, in one embodiment of the invention had openings of about 1 mm corresponding to the spacing of the spheres in the previous embodiments to block frequencies having a wavelength of fro example about 14.4 GHz. Again, the edges of shield 330 are surrounded by solder spheres 332 bonded to the edges of the mesh 338 to provide surface mount capability of the shield 330 to an existing circuit board with the solder spheres being aligned with grounded conductive pads or ribbon conductors on the underlying circuit board or circuit package. Instead of a mesh material 338, the mesh pattern can be screen printed onto substrate 334 utilizing a screen printing and masking process. The mesh size can be varied according to the 1/20 relationship described above for blocking selective frequency interference.

Finally, FIG. 7 illustrates yet another embodiment of the invention in which a shield 430 is employed and includes a substrate 434, and a conductive element, such as 436, which can be a solid film of conductive material, such as copper as in the previous embodiments, or a wire mesh, such as mesh 338 in the embodiment shown in FIG. 6. Instead of a single row of solder spheres, this embodiment employs a plurality of rows 501 and 502 of solder spheres 432. These rows may be aligned or alternately staggered to provide spacing between the spheres for blocking predetermined frequency interference from entering the circuit component being shielded. In this manner, the shielding effect of the solder spheres themselves can be adjusted and chosen to block the undesirable RF/EMI interference.

It will be understood by those who practice the invention and those skilled in the art, that various modifications and improvements may be made to the invention without departing from the spirit of the disclosed concept. The scope of protection afforded is to be determined by the claims and by the breadth of interpretation allowed by law.

1. An RF/EMI shield for an electrical component comprising:
a generally planar conductive element; and
a plurality of solder spheres extending around a central section of said conductive element and bonded to said conductive member.

2. The shield as defined in claim 1 wherein said spheres have a diameter selected to space said conductive member in proximity to a circuit component being shielded.

3. The shield as defined in claim 2 wherein said conductive element comprises a solid sheet of conductive material.

4. The shield as defined in claim 3 wherein said material is copper

5. The shield as defined in claim 2 wherein said conductive element comprises a mesh pattern.

6. The shield as defined in claim 5 wherein said mesh pattern is defined by a wire mesh.

7. The shield as defined in claim 5 wherein said shield includes a nonconductive substrate and said mesh pattern is formed by screen printing onto said substrate.

8. The shield as defined in claim 1 wherein said shield includes a nonconductive substrate to which said conductive element is bonded.

9. The shield as defined in claim 8 wherein said spheres have a diameter of from about 1 mm to about 2 mm.

10. The shield as defined in claim 9 wherein said spheres are positioned on the edges of said conductive element and are spaced apart a distance of from about 1 mm to about 6 mm.

11. The shield as defined in claim 1 wherein said conductive element is divided into a plurality of sections by at least one row of solder spheres.

12. The shield as defined in claim 1 wherein said shield comprises a nonconductive substrate to which said conductive element is bonded and wherein said substrate and element have a non-symmetrical shape.

13. The shield as defined in claim 12 wherein said shield is generally L-shaped.

14. The shield as defined in claim 1 wherein said shield includes a plurality of rows of solder spheres extending around the periphery of said conductive element.

15. A surface mounted shield for an electrical component comprising:
a generally planar conductive element; and
a plurality of spheres extending around a central section of said conductive element and bonded to said conductive member.

16. The shield as defined in claim 15 wherein said spheres are made of solder and have a diameter selected to space said conductive member in proximity to a circuit component being shielded.

17. The shield as defined in claim 16 wherein said conductive element comprises a mesh pattern.

18. The shield as defined in claim 17 wherein said mesh pattern is defined by a wire mesh.

19. The shield as defined in claim 15 wherein said shield includes a nonconductive substrate to which said conductive element is bonded.

20. An RF/EMI shield for an electrical component comprising:
a nonconductive substrate;
a generally planar conductive element coupled to said substrate; and
a plurality of solder spheres extending around a central section of said conductive element and bonded to said conductive member.

21. The shield as defined in claim 20 wherein said conductive element comprises a sheet of copper.

22. The shield as defined in claim 20 wherein said conductive element comprises a mesh pattern.

23. The shield as defined in claim 22 wherein said mesh pattern is defined by a wire mesh.

24. The shield as defined in claim 22 wherein said mesh pattern is formed by screen printing onto said substrate.

25. The shield as defined in claim 20 wherein said spheres have a diameter of from about 1 mm to about 2 mm.

26. The shield as defined in claim 20 wherein said spheres are positioned on the edges of said conductive element and are spaced apart a distance of from about 1 mm to about 6 mm.

27. An RF/EMI shield for an electrical component comprising:
a generally planar conductive element; and
a plurality of solder spheres extending around a central section of said conductive element and bonded to said conductive member, wherein said conductive element is divided into a plurality of sections by at least one row of solder spheres.

28. The shield as defined in claim 27 wherein said shield comprises a nonconductive substrate to which said conductive element is bonded and wherein said substrate and element have a non-symmetrical shape.

29. The shield as defined in claim 27 wherein said shield is generally L-shaped.

30. The shield as defined in claim 27 wherein said shield includes a plurality of rows of solder spheres extending around the periphery of said conductive element.

31. An RF/EMI shield for an electrical component comprising:
a generally planar conductive element; and
a plurality of solder spheres extending around a central section of said conductive element and bonded to said conductive member, wherein said shield includes a plurality of rows of solder spheres extending around the periphery of said conductive element.
